(19) United States
(12) Patent Application Publication
(10) Pub. No.: US 2009/0230502 A1
(43) Pub. Date: Sep. 17, 2009

(54) SEMICONDUCTOR DEVICE AND METHOD FOR MANUFACTURING THE SAME

(75) Inventor: Yoji KITANO, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 12/389,658

(22) Filed: Feb. 20, 2009

(30) Foreign Application Priority Data
Mar. 11, 2008 (JP) 2008-061159

(51) Int. Cl. H01L 29/12; H01L 21/336

(52) U.S. Cl. 257/506; 438/299; 438/296; 257/E21.409; 257/E29.068

(57) ABSTRACT

A method for manufacturing a semiconductor device includes: forming a first semiconductor layer on a semiconductor substrate; forming a second semiconductor layer on the first semiconductor layer; forming a first groove which penetrates the first and the second semiconductor layers by etching the first and the second semiconductor layers; forming a support in the first groove; forming a second groove so that the first semiconductor layer is exposed by etching the second semiconductor layer; forming a cavity between the second semiconductor layer and the semiconductor substrate by etching the first semiconductor layer through the second groove; and forming an insulating film inside the cavity. In the step of forming the second groove, the second semiconductor layer is formed so as to have a first region, a second region, and a third region in a plan view. The first groove includes a plurality of first grooves. The first region is sandwiched between the first grooves in a first direction in the plan view. The second region is sandwiched between the first grooves in the first direction in the plan view and is provided parallel to the first region along a second direction which intersects with the first direction. The third region links the first and the second regions while being adjacent to the second groove.

### BACKGROUND

1. Technical Field

The present invention relates to a method for manufacturing a semiconductor device and a semiconductor device. More particularly, the invention relates to a technique for partially forming a silicon-on-insulator (SOI) structure on a semiconductor substrate.

2. Related Art

JP-A-2005-354024 is an example of a related art. A method disclosed in the example is called an SBSI method in which the SOI structure is partially formed on a bulk Si substrate. In the SBSI method, a Si layer and a SiGe layer are sequentially formed on a Si substrate, and only the SiGe layer is selectively removed by using an etching rate difference between Si and SiGe so as to form a cavity between the Si substrate and the Si layer. At this time, a side surface of the Si layer is supported by an insulating support formed on the Si substrate. An upper surface of the Si substrate and a lower surface of the Si layer facing an interior of the cavity are thermally oxidized so as to form a SiO₂ film (hereinafter also referred to as a BOX layer) between the Si substrate and the Si layer. Then a SiO₂ film and the like are formed on the Si substrate by a chemical vapor deposition (CVD) method, and they are planarized by a chemical mechanical polish (CMP) and etched by a diluted hydrofluoric acid (HF) solution and the like so that a surface of the Si layer (hereinafter also called as an SOI layer) formed on the BOX layer is exposed. Accordingly, an SOI structure composed of the BOX layer and the SOI layer is completed on the Si substrate.

As FIG. 16A shows, an SOI layer 105 is completely isolated from a Si substrate 101 by a BOX layer 123, an insulating support 107 and the like. After the SOI structure is formed as described, a gate insulating film 141 is formed on the SOI layer 105, and a gate electrode 143 is formed on the gate insulating film 141, for example. Then, an impurity is ion-implanted into the SOI layer 105 at the both sides of the gate electrode 143 and a heat treatment is performed so as to form a source and a drain (hereafter also referred to as an S/D layer) 145. Accordingly, a MOS transistor is completed.

The MOS transistor shown in FIG. 16A, when its channel length is increased, as shown in FIG. 16B, for example, an area of the SOI layer 105 requires a large area by increasing a distance between the supports 107. However, the support 107 functions as a support member for the SOI layer 105 in the process from forming a cavity to forming the BOX layer 123 and the like. Therefore, when the distance between the supports 107 is increased too much, the supports 107 can hardly support the SOI layer 105 when the BOX layer 123 and the like are formed, so that the SOI layer 105 may be removed.

### SUMMARY

An advantage of the invention is to provide a method for manufacturing a semiconductor device and a semiconductor device which allows the SOI layer to have a large area and also preventing the SOI layer from being removed.

According to a first aspect of the invention, a method for manufacturing a semiconductor device includes: forming a first semiconductor layer on a semiconductor substrate; forming a second semiconductor layer on the first semiconductor layer; forming a first groove which penetrates the first and the second semiconductor layers by etching the first and the second semiconductor layers; forming a support in the first groove; forming a second groove so that the first semiconductor layer is exposed by etching the second semiconductor layer; forming a cavity between the second semiconductor layer and the semiconductor substrate by etching the first semiconductor layer through the second groove; and forming an insulating film inside the cavity. In the step of forming the second groove, the second semiconductor layer is formed so as to have a first region, a second region, and a third region in a plan view. The first groove includes a plurality of first grooves. The first region is sandwiched between the first grooves in a first direction in the plan view. The second region is sandwiched between the first grooves in the first direction in the plan view and is provided parallel to the first region along a second direction which intersects with the first direction. The third region links the first and the second regions while being adjacent to the second groove.

Here, the “semiconductor substrate” of the invention is, for example, a bulk silicon (Si) substrate, the “first semiconductor layer” is, for example, a single-crystalline silicon germanium (SiGe) layer, and the “second semiconductor layer” is, for example, a single-crystalline Si layer. The SiGe layer and the Si layer are formed by an epitaxial growth, for example. Further, the “support” and the “insulating film” of the invention are the insulating film composed of a silicon oxide (SiO₂) film or a silicon nitride (Si₃N₄) film, for example.

In the method, the second groove may include a plurality of second grooves. The third region may be sandwiched between the second grooves in the first direction in the plan view.

In the method, each of the first, the second, and the third regions may have a rectangular shape in the plan view, and may satisfy a relation of L1>L3 and L2>L3 where L1 is a length of the first region along the first direction, L2 is the length of the second region along the first direction, and L3 is the length of the third region along the first direction.

According to the method, linking the first region and the second region which are supported by the support with the third region enables the second semiconductor layer to be stretched in the plan view. Therefore, an interval between the first grooves is not necessary to be increased. It allows preventing the second semiconductor layer from being removed, and also allows increasing an area thereof. In particular, according to the method, a hydrofluoric-nitric acid solution can be easily introduced under the third region through the second groove. Therefore, an etching residue of the first semiconductor layer can be prevented, and an etching time can be reduced.

In the step of forming the second groove in the method, if the second semiconductor layer is viewed in the plan view, the first and the second regions may be alternately provided along the second direction, and the third region may be provided between the first and the second regions. According to the method, the second semiconductor layer can be stretched more in proportion to the number of the first, the second, and the third regions provided thereon.

In the step of forming the second groove in the method, if the second semiconductor layer is viewed in the plan view, the third region may be alternately provided from side to side in the second direction. Here, “alternately provided from side to side” means that it is provided in a staggering manner. According to the method, the second semiconductor layer is formed in a so-called meandering manner in the plan view. Therefore, the second semiconductor layer can be efficiently stretched within a limited device area.

The method may include forming a gate electrode on the second semiconductor layer with a gate insulating film therebetween, and forming a source and a drain by doping an impurity into the second semiconductor layer using the gate electrode as a mask. In the step of forming the gate electrode, the gate electrode may be formed from the first region to the second region through the third region. In the step of forming the source and the drain, one of the source and the drain may be formed at a side adjacent to one end in a longitudinal direction of the gate electrode, and the other of the source and the drain may be formed at a side adjacent to the other end in the longitudinal direction. According to the method, a MOS transistor having a long channel length can be formed at the SOI structure formed by a so-called SBSI method.

According to a second aspect of the invention, a semiconductor device includes: a semiconductor substrate; a first semiconductor layer formed on the semiconductor substrate; a second semiconductor layer formed on the first semiconductor layer with a first insulating film therebetween; and an element isolation film formed on the semiconductor substrate so as to surround the second semiconductor layer in a plan view. In the device, the element isolation film includes a first insulating film and a second insulating film, and the first insulating film includes a plurality of first insulating films. The second semiconductor layer in a plane view includes a first region, a second region, and a third region. The first region is sandwiched by the first insulating films in a first direction. The second region is sandwiched by the first insulating films in the first direction, and is placed apart from and faces to the first region. The third region is adjacent to the second insulating film in the first direction and links the first and the second regions in a second direction.

### BRIEF DESCRIPTION OF THE DRAWINGS

The invention will be described with reference to the accompanying drawings, wherein like numbers reference like elements.

FIGS. 1A and 1B are diagrams illustrating a method for manufacturing a semiconductor device according to an embodiment.

FIGS. 2A, 2B, and 2C are diagrams illustrating the method for manufacturing the semiconductor device according to the embodiment.

FIGS. 3A, 3B, and 3C are diagrams illustrating the method for manufacturing the semiconductor device according to the embodiment.

FIGS. 4A, 4B, 4C, and 4D are diagrams illustrating the method for manufacturing the semiconductor device according to the embodiment.

FIGS. 5A, 5B, 5C, and 5D are diagrams illustrating the method for manufacturing the semiconductor device according to the embodiment.

FIGS. 6A, 6B, 6C, and 6D are diagrams illustrating the method for manufacturing the semiconductor device according to the embodiment.

FIGS. 7A, 7B, 7C, and 7D are diagrams illustrating the method for manufacturing the semiconductor device according to the embodiment.

FIGS. 8A, 8B, 8C, and 8D are diagrams illustrating the method for manufacturing the semiconductor device according to the embodiment.

FIGS. 9A, 9B, 9C, and 9D are diagrams illustrating the method for manufacturing the semiconductor device according to the embodiment.

FIGS. 10A, 10B, and 10C are diagrams illustrating the method for manufacturing the semiconductor device according to the embodiment.

FIGS. 11A, 11B, and 11C are diagrams illustrating the method for manufacturing the semiconductor device according to the embodiment.

FIGS. 12A, 12B, 12C, 12D, and 12E are diagrams illustrating the method for manufacturing the semiconductor device according to the embodiment.

FIG. 13 is a diagram showing an example of a planar shape of a Si layer (SOI layer) 5.

FIGS. 14A and 14B are diagrams showing examples of the planar shape of the Si layer (SOI layer) 5.

FIGS. 15A and 15B are diagrams showing examples of the planar shape of the Si layer (SOI layer) 5.

FIGS. 16A and 16B are diagrams explaining a problem of a related art.

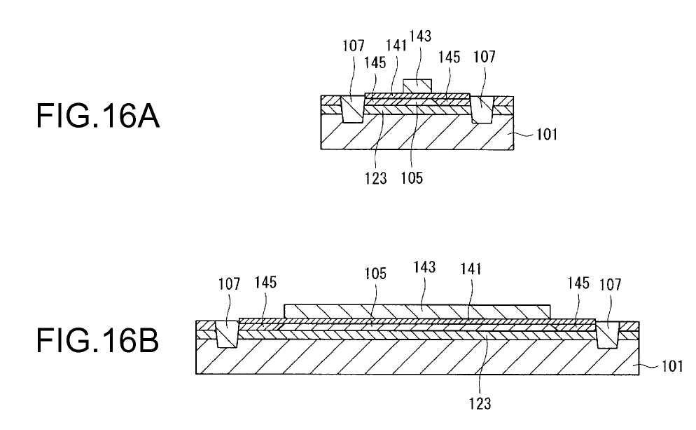

### DESCRIPTION OF EXEMPLARY EMBODIMENT

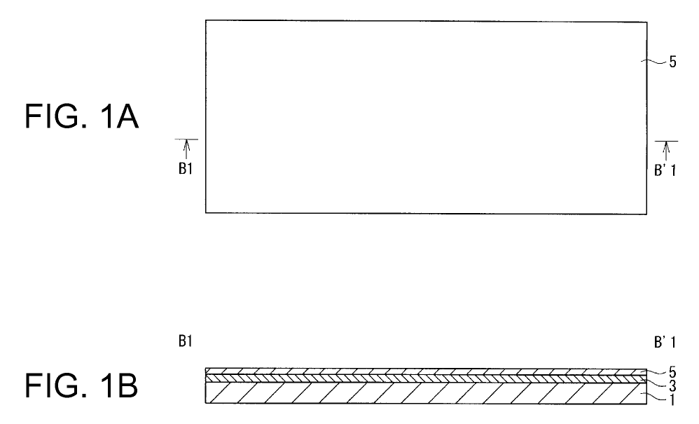

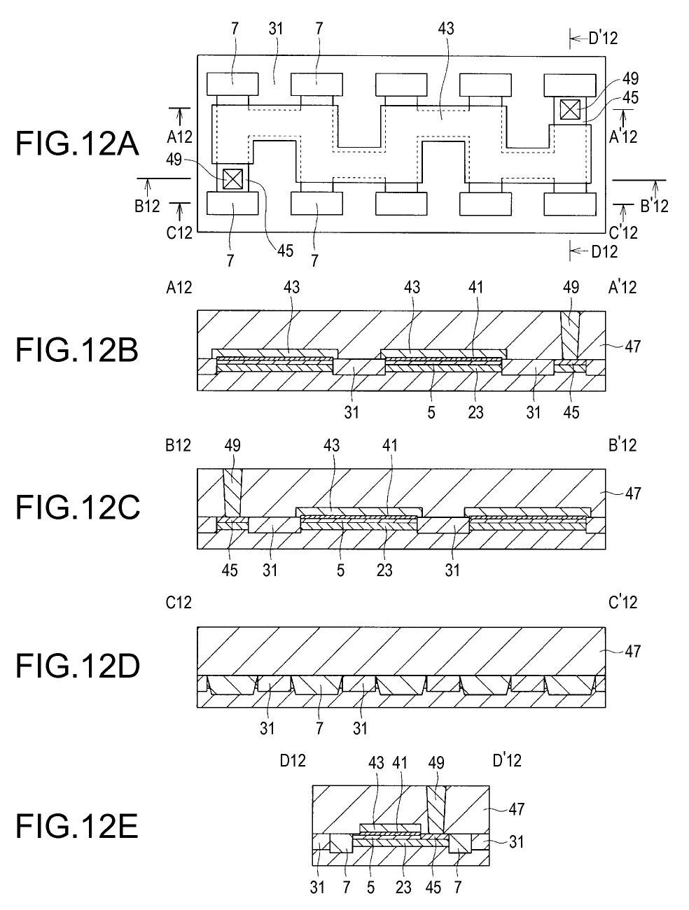

An embodiment of the present invention will now be described with reference to the accompanying drawings below. The same numerals are given to the same structure, and the overlapped description thereof will be omitted. FIGS. 1A to 12E are schematic views showing a method for manufacturing a semiconductor device according to the embodiment of the invention. Each of A Figs. is a schematic plan view, and the corresponding Figs. from B to E are cross sectional views of respective Figs. A. In FIG. 12A, an interlayer insulation film 47 is omitted to simplify the drawing.

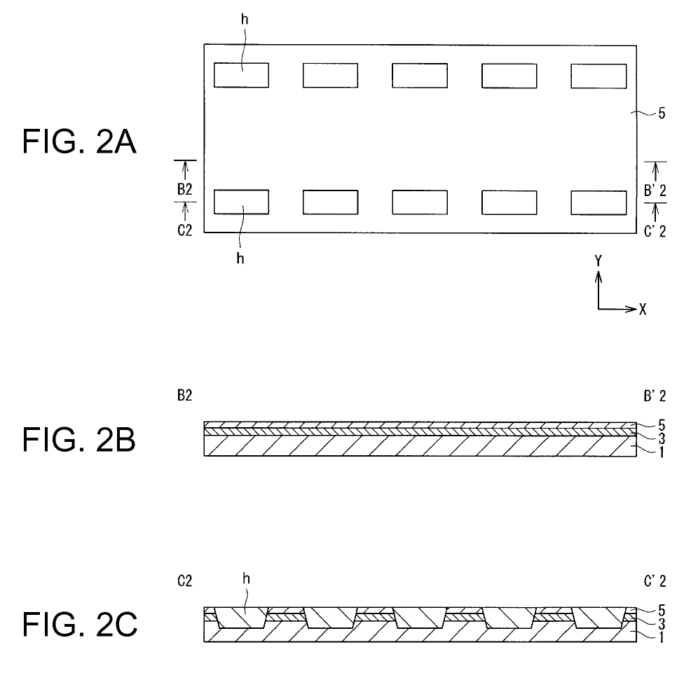

As shown in FIGS. 1A and 1B, a silicon-germanium (SiGe) layer 3 is formed on a bulk silicon (Si) substrate 1, and a single-crystalline silicon (Si) layer 5 is formed on the top thereof. The SiGe layer 3 and the Si layer 5 are formed in succession by an epitaxial growth method, for example. Next, as shown in FIGS. 2A to 2C, using a photolithography technique and an etching technique, the Si layer 5 and the SiGe layer 3 are partially etched. Accordingly, a support hole h having the Si substrate 1 as a bottom surface thereof is formed in a region that is overlapped with an element isolation region (i.e., a region where a silicon-on-insulator (SOI) structure is not formed) in a plan view. As shown in the plan view, a plurality of a pair of the support holes h facing to each other in a Y direction are provided with a predetermined interval in an X direction which is orthogonal to the Y direction. In the etching process in FIGS. 2A to 2C, the etching may be performed until reaching a surface of the Si substrate 1, or the substrate 1 may be over-etched to form a concave portion thereon.

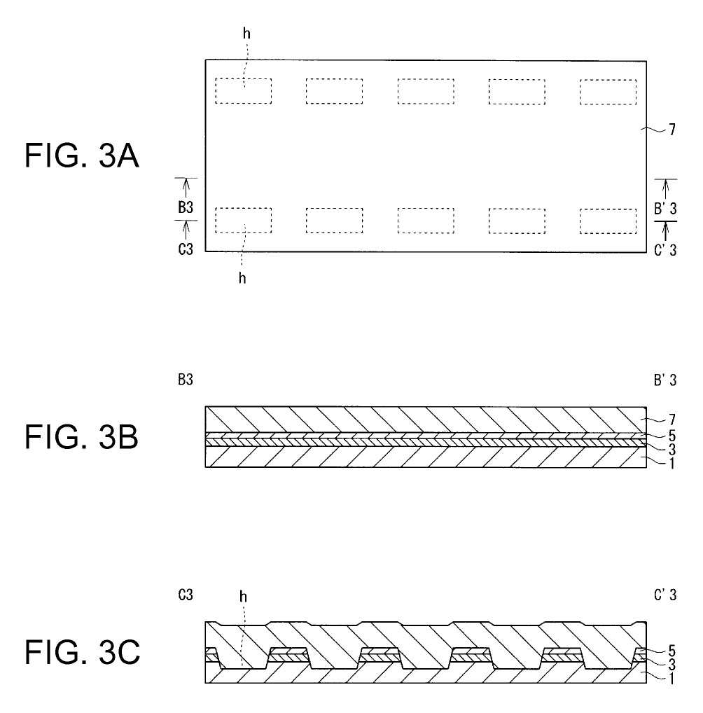

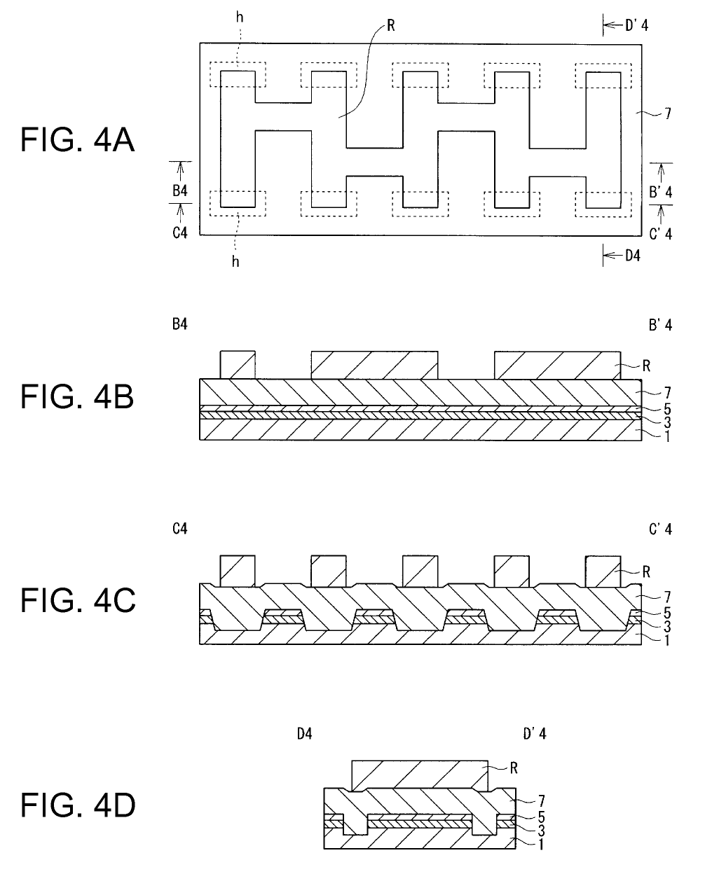

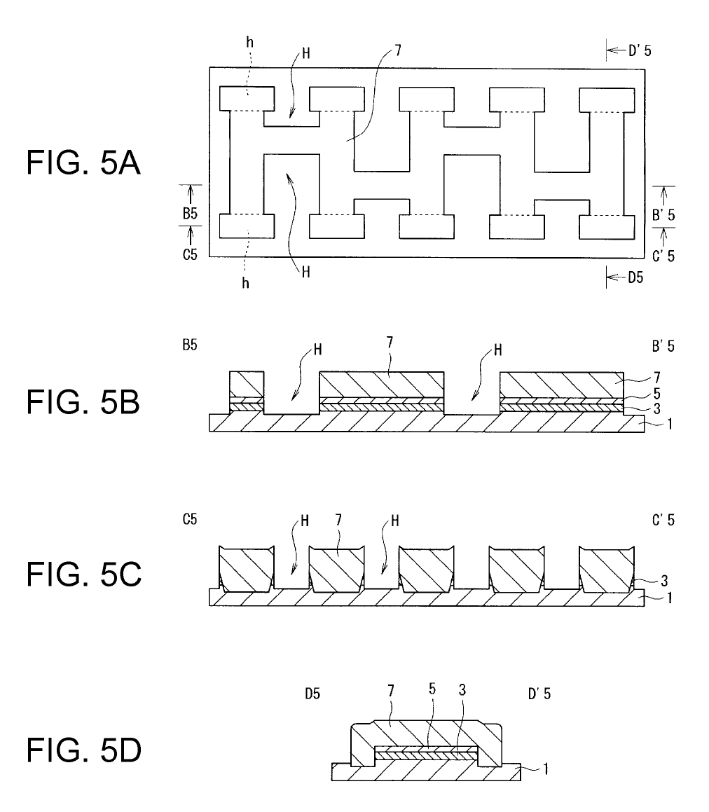

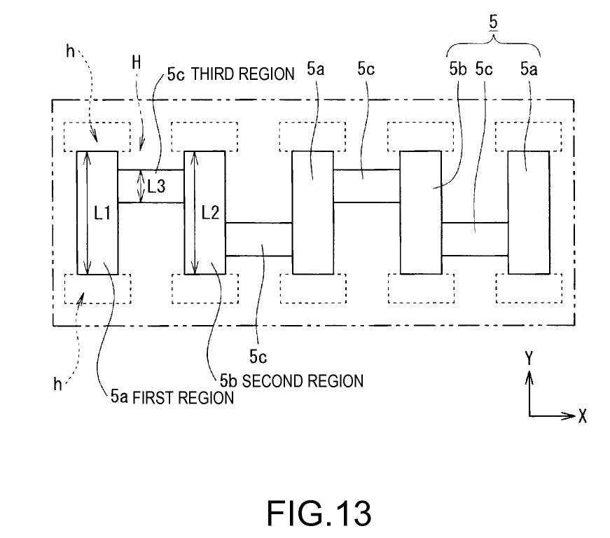

Next, as shown in FIGS. 3A to 3C, a silicon oxide (SiO₂) film 7 is formed on the surface of the Si substrate 1 so as to fill the support holes h. The SiO₂ film 7 is formed by a chemical vapor deposition (CVD) method, for example. As shown in FIGS. 4A to 4D, a resist pattern R having a predetermined shape is provided on the SiO₂ film 7, and the SiO₂ film 7, the Si layer 5, and the SiGe layer 3 are sequentially etched by using the resist pattern R as a mask. As a result, as shown in FIGS. 5A to 5D, a support is formed from the SiO₂ film 7, and a groove H having the Si substrate 1 as a bottom surface thereof are formed in a region that is overlapped with the element isolation region in the plan view. In addition, when the Si layer 5 is viewed in the plan view, a first region, a second region, and a third region are formed thereon. The first region, the second region, and the third region will now be described with reference to FIG. 13.

FIG. 13 is a diagram schematically showing an example of the Si layer 5 in the plan view (hereafter referred to as a planar shape). As shown in FIG. 13, a first region 5a is sandwiched between the support holes h in the Y direction. A second region 5b which is sandwiched between the support holes h in the Y direction and faces to the first region in the X direction. A third region 5c is sandwiched between the support holes h in the Y direction and links the first region 5a and the second region 5b in the X direction.

As shown in FIG. 13, each planar shape of the first region 5a, the second region 5b, and the third region 5c has a rectangular shape, for example. The first region 5a and the second region 5b are provided alternately in the X direction while the third region 5c is provided between the first region 5a and the second region 5b. As FIG. 13 shows, L1=L2>L3 when L1 is a length of the first region 5a along the Y direction, L2 is the length of the second region 5b along the Y direction, and L3 is the length of the third region 5c along the Y direction. Further, the third region 5c is alternately provided from side to side in the X direction (i.e., in a staggering manner). Thus, the Si layer 5 includes the first region 5a, the second region 5b, and the third region 5c, and its planar shape is in a so-called meandering manner. In the etching process in FIGS. 5A to 5D, the etching may be performed until reaching the surface of the Si substrate 1, or the substrate 1 may be over-etched to form a concave portion thereon.

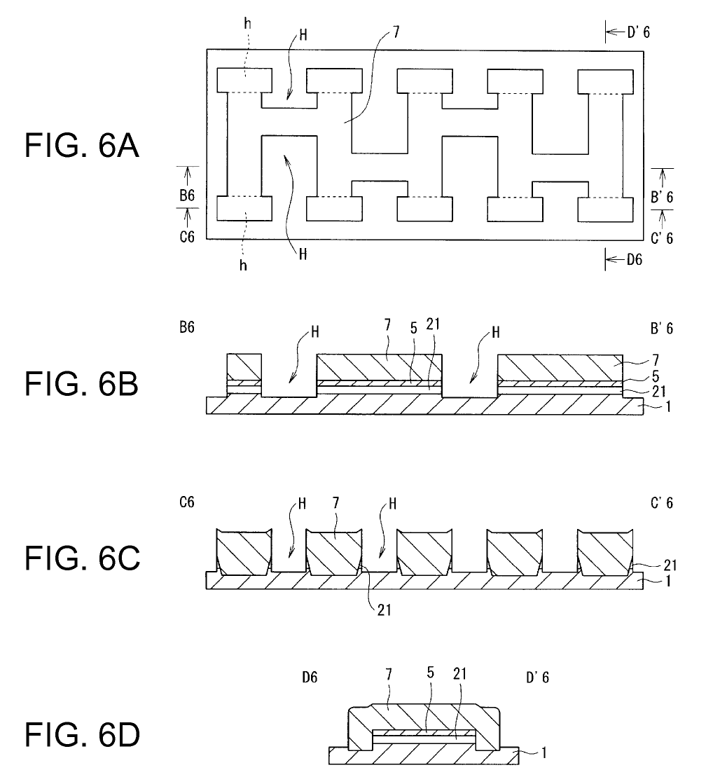

In FIGS. 5A to 5D, an etchant, such as a hydrofluoric-nitric acid solution is brought into contact with each side surface of the Si layer 5 and the SiGe layer 3 through the groove H so as to selectively remove the SiGe layer 3 by the etching. Accordingly, as shown in FIGS. 6A to 6D, a cavity 21 is formed between the Si layer 5 and the Si substrate 1. In a wet-etching using the hydrofluoric-nitric acid solution, since an etching rate of the SiGe is higher than that of the Si (i.e., an etching selectivity of the SiGe with respect to the Si is high), only the SiGe layer 3 can be etched and removed while the Si layer 5 is left. After forming the cavity 21, the Si layer 5 is supported by the support (SiO₂ film) 7. In an etching process of the SiGe layer 3 above, a hydrofluoric-nitric acid hydrogen peroxide, an ammonia hydrogen peroxide, or a hydrofluoric-acetic acid hydrogen peroxide may be used instead of the hydrofluoric-nitric acid solution. In this case as well, the etching rate of the SiGe is higher than that of the Si so as to selectively remove the SiGe layer 3.

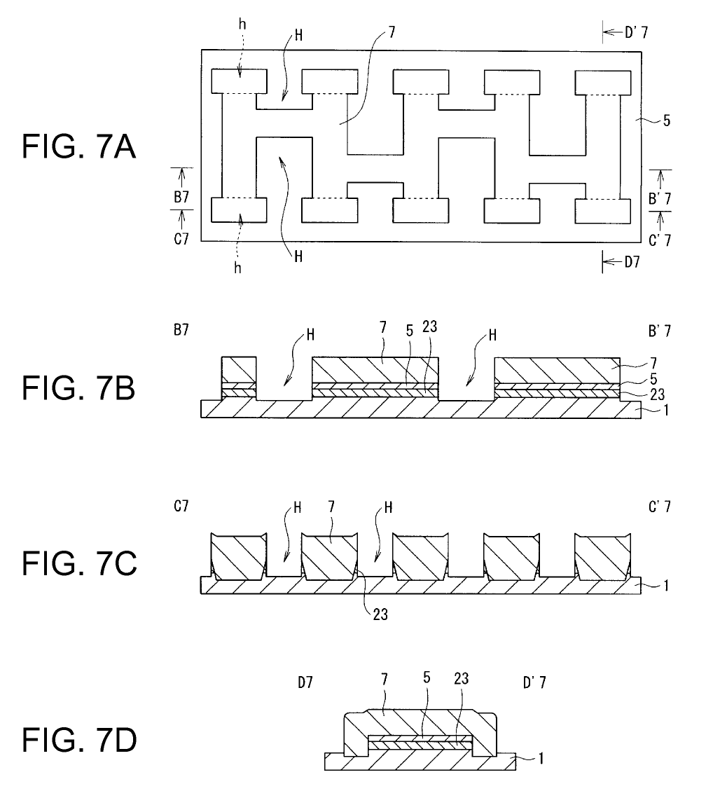

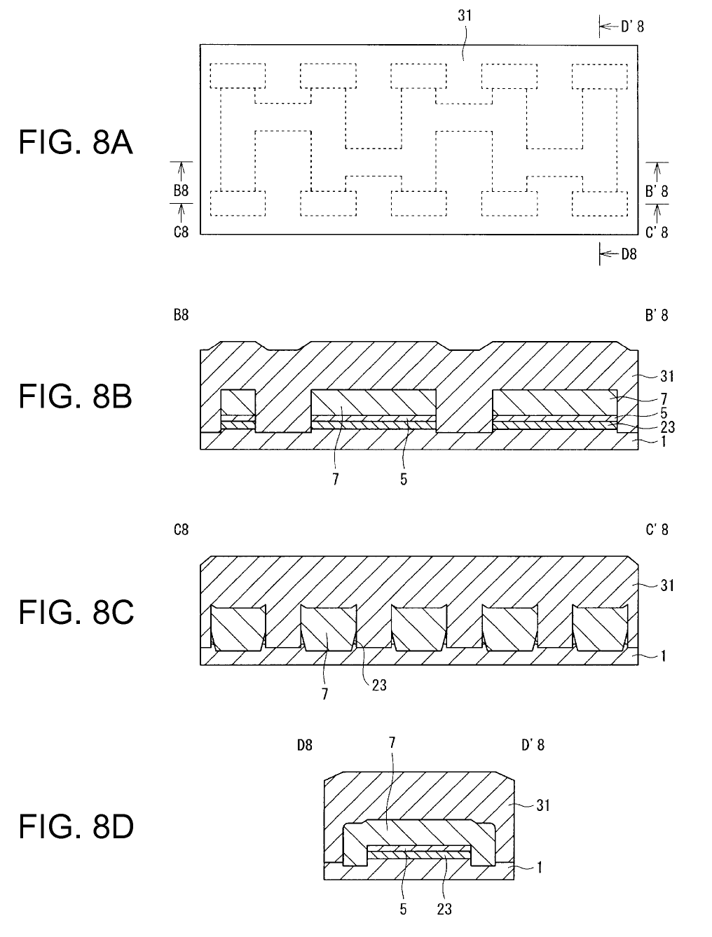

Next, as shown in FIGS. 7A to 7D, a SiO₂ film 23 is formed on the Si substrate 1 so as to completely fill the cavity. The SiO₂ film 23 is formed by a thermal oxidation, the CVD method, or a film forming method of which a combination of the thermal oxidation and the CVD method, for example. Forming the SiO₂ film 23 by the CVD method or the film forming method of the combination of the thermal oxidation and the CVD method makes the SiO₂ film 23 thick so as to completely fill both the cavity and the groove H. As shown in FIGS. 8A to 8D, a SiO₂ film 31, for example, is formed on the Si substrate 1 so as to completely fill the groove H. The SiO₂ film 31 is formed by the CVD method.

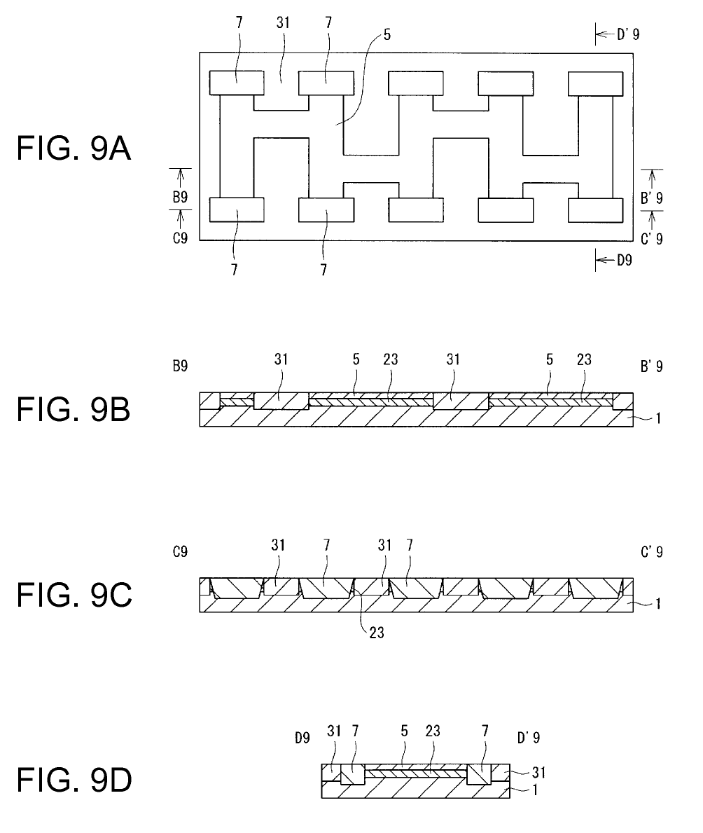

As shown in FIGS. 9A to 9D, the SiO₂ layer is planarized and removed by a chemical mechanical polish (CMP) so that a surface of the Si layer 5 is exposed. Accordingly, a silicon-on-insulator (SOI) structure composed of the SiO₂ layer (i.e. a BOX layer) 23 and the Si layer (i.e. an SOI layer) 5 is completed on the bulk Si substrate 1. In addition, in a planarizing process above, the CMP is performed until a state that the SiO₂ layer 7 slightly remains on the Si layer 5, and it is preferable that the remaining SiO₂ layer 7 is removed by the wet-etching using a dilute hydrofluoric acid (DHF), for example. This allows preventing the surface of the Si layer 5 from being damaged by the CMP.

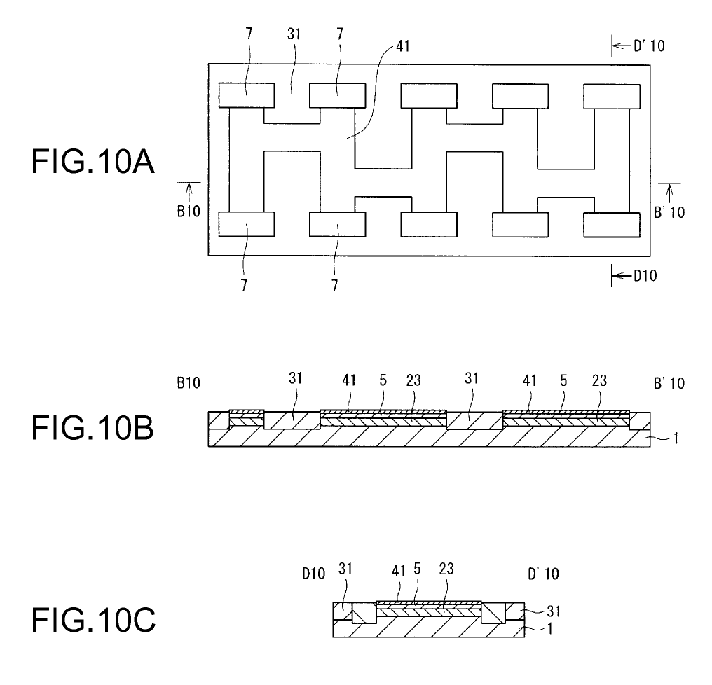

Thereafter, a MOS transistor is formed on the SOI layer 5, for example. Specifically, as shown in FIGS. 10A to 10C, a gate insulating film 41 is formed on the surface of the SOI layer 5. The gate insulating film 41 is composed of, for example, the SiO₂ film formed by the thermal oxidation or a silicon oxynitride film (SiON), or a high-k material film. Then, a polysilicon (poly-Si) film is formed on an entire surface of the SOI substrate on which the gate insulating film 41 is formed. The polysilicon film is formed by the CVD method, for example. Here, an impurity is ion-implanted into the polysilicon film or doped with an in-situ method so as to provide conductivity to the polysilicon film.

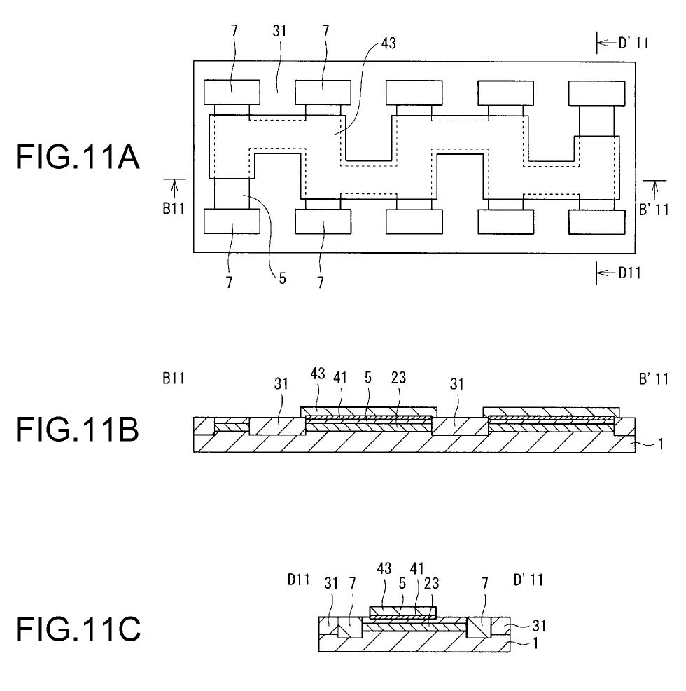

Then, as shown in FIGS. 11A to 11C, the polysilicon film is partially etched by the photolithography technique and the etching technique so as to form a gate electrode 43. Here, the gate electrode 43 is formed from the first region 5a to the second region 5b through the third region 5c. Thus, the planar shape of the gate electrode 43 is in the meandering manner as well as the SOI layer 5.

Next, as shown in FIGS. 12A to 12E, the impurity is ion-implanted into the SOI layer 5, and performed a heat treatment to form an S/D layer 45 using the gate electrode 43 as a mask. Here, a source is formed at a side adjacent to one end in a longitudinal direction of the gate electrode 43 (e.g., the left side in FIG. 12A) while a drain is formed at a side adjacent to the other end in the longitudinal direction (e.g., the right side in FIG. 12A). Then, as shown in FIGS. 12B to 12E, an interlayer insulation film 47 is formed on the entire upper surface of the Si substrate 1. The interlayer insulation film 47 is partially etched by the photolithography technique and the etching technique so as to form a contact hole on the S/D layer 45. Furthermore, a plug electrode 49 is formed in the contact hole so that the S/D layer 45 is pulled out on the interlayer insulation film 47. Accordingly, a MOS transistor is completed.

As described above, according to the embodiment of the invention, linking the first region 5a and the second region 5b which are supported by the support 7 with the third region 5c enables the SOI layer 5 to be stretched in the plan view. Therefore, an interval between the support holes h is not necessary to be increased. It allows preventing the SOI layer 5 from being removed, and also allows increasing an area thereof. In addition, the third region 5c is sandwiched by the grooves H in the Y direction in the plan view. The length L3 of the third region 5c along the Y direction is shorter than the length L1 and the length L2. The length L1 is the length of the first region 5a along the Y direction, and the length L2 is the length of the second region 5b along the Y direction. Therefore, the hydrofluoric-nitric acid solution is easily introduced under the third region 5c so that an etching residue of the SiGe layer 3 can be prevented and an etching time of the SiGe layer 3 can be reduced.

Further, the SOI layer 5 is formed in the so-called meandering manner in the plan view. As a result, the SOI layer 5 can be efficiently stretched within a limited device area so as to form the MOS transistor having a long channel length. In the embodiment, the Si substrate 1 exemplary corresponds to a “semiconductor substrate” of the invention, and the SiGe layer 3 exemplary corresponds to a “first semiconductor layer” of the invention. The Si layer (SOI layer) 5 exemplary corresponds to a “second semiconductor layer” of the invention, and the SiO₂ film (BOX film) 23 exemplary corresponds to an “insulating film” of the invention. The support hole h exemplary corresponds to a “first groove” of the invention, and the groove H exemplary corresponds to a “second groove” of the invention. Further, the SiO₂ film 7 exemplary corresponds to a “support” or a “first insulating film” of the invention, and the SiO₂ film 31 exemplary corresponds to a “second insulating film” of the invention. The Y direction exemplary corresponds to a “first direction” of the invention, and the X direction exemplary corresponds to a “second direction” of the invention.

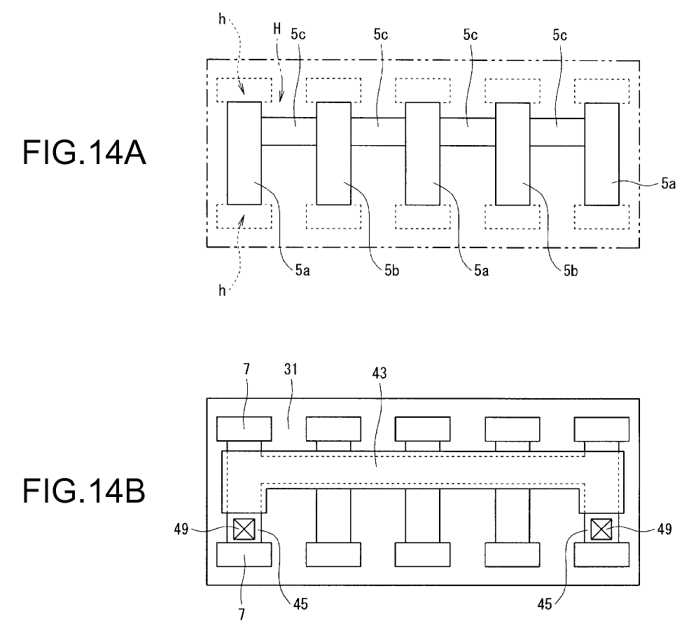

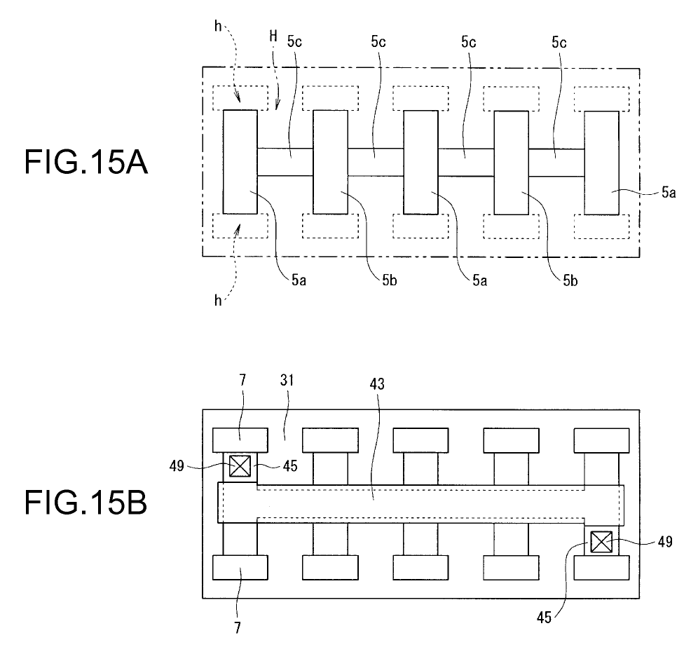

In the embodiment above, as shown in FIG. 13, a case where the third region 5c is alternately provided from side to side in the X direction and the planar shape of the SOI layer 5 is in the meandering manner is explained. However, the planer shape of the SOI layer 5 is not limited to the meandering manner. For example, as shown in FIGS. 14A and 15A, the third region 5c may be formed in a straight line along the X direction.

In a case when the third region 5c is provided in this way, the first region 5a and the second region 5b which are supported by the support can be linked with the third region 5c so that the SOI layer 5 can be stretched in the plan view. As well as the above embodiment, an interval of the grooves H is not necessary to be increased. It allows preventing the SOI layer 5 from being removed, and also allows increasing an area thereof. As shown in FIGS. 14B and 15B, the gate electrode 43 is formed from the first region 5a to the second region 5b through the third region 5c. Forming the S/D layer 49 at both sides adjacent to both ends in the longitudinal direction of the gate electrode 43 enables the MOS transistor having a long channel length to be formed.

The entire disclosure of Japanese Patent Application No. 2008-061159, filed Mar. 11, 2008 is expressly incorporated by reference herein.

What is claimed is:

1. A method for manufacturing a semiconductor device, comprising:
forming a first semiconductor layer on a semiconductor substrate;
forming a second semiconductor layer on the first semiconductor layer;
forming a first groove which penetrates the first and the second semiconductor layers by etching the first and the second semiconductor layers;
forming a support in the first groove;
forming a second groove so that the first semiconductor layer is exposed by etching the second semiconductor layer, wherein the second semiconductor layer is formed so as to have a first region, a second region, and a third region in a plan view, wherein: the first groove includes a plurality of first grooves; the first region is sandwiched between the first grooves in a first direction in the plan view; the second region is sandwiched between the first grooves in the first direction in the plan view and is provided parallel to the first region along a second direction which intersects with the first direction; and the third region links the first and the second regions while being adjacent to the second groove;
forming a cavity between the second semiconductor layer and the semiconductor substrate by etching the first semiconductor layer through the second groove; and
forming an insulating film inside the cavity.

2. The method for manufacturing the semiconductor device according to the claim 1, wherein the second groove includes a plurality of second grooves, the third region is sandwiched between the second grooves in the first direction in the plan view.

3. The method for manufacturing the semiconductor device according to the claim 1, wherein each of the first, the second, and the third regions has a rectangular shape in the plan view, and satisfies a relation of L1>L3 and L2>L3, wherein L1 is a length of the first region along the first direction, L2 is the length of the second region along the first direction, and L3 is the length of the third region along the first direction.

4. The method for manufacturing the semiconductor device according to the claim 1, wherein, in the forming the second groove, if the second semiconductor layer is viewed in the plan view, the first and the second regions are alternately provided along the second direction, and the third region is provided between the first and the second regions.

5. The method for manufacturing the semiconductor device according to the claim 4, wherein, in the forming the second groove, if the second semiconductor layer is viewed in the plan view, the third region is alternately provided from side to side in the second direction.

6. The method for manufacturing the semiconductor device according to the claim 1, further comprising forming a gate electrode on the second semiconductor layer with a gate insulating film therebetween, and forming a source and a drain by doping an impurity into the second semiconductor layer using the gate electrode as a mask, wherein, in the forming the gate electrode, the gate electrode is formed from the first region to the second region through the third region, and in the forming the source and the drain, one of the source and the drain is formed at a side adjacent to one end in a longitudinal direction of the gate electrode, and another of the source and the drain is formed at a side adjacent to another end in the longitudinal direction.

7. A semiconductor device, comprising:
a semiconductor substrate;
a first semiconductor layer formed on the semiconductor substrate;
a second semiconductor layer formed on the first semiconductor layer with a first insulating film therebetween; and
an element isolation film formed on the semiconductor substrate so as to surround the second semiconductor layer in a plan view, wherein the element isolation film includes a first insulating film and a second insulating film, wherein the first insulating film includes a plurality of first insulating films, and the second semiconductor layer in a plane view includes a first region which is sandwiched by the first insulating films in a first direction, a second region which is sandwiched by the first insulating films in the first direction and is placed apart from and faces to the first region, and a third region which is adjacent to the second insulating film in the first direction and links the first and the second regions in a second direction.
